(19) United States
(12) Patent Application Publication
(10) Pub. No.: US 2010/0003495 A1
(43) Pub. Date: Jan. 7, 2010

(54) TRANSPARENT CONDUCTIVE FILM AND METHOD FOR MANUFACTURING THE TRANSPARENT CONDUCTIVE FILM, AND SPUTTERING TARGET USED IN THE METHOD

(75) Inventors: Ichiro Hayashi, Tokyo (JP); Hidefumi Odaka, Tokyo (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: Asahi Glass Company, Limited, Tokyo (JP)

(21) Appl. No.: 12/559,034

(22) Filed: Sep. 14, 2009

Related U.S. Application Data
(63) Continuation of application No. PCT/JP2008/050375, filed on Jan. 15, 2008.

(30) Foreign Application Priority Data
Mar. 14, 2007 (JP) 2007-064690

(51) Int. Cl. B32B 9/00; B32B 5/00; C23C 14/34; H01B 1/22; H01B 1/08

(52) U.S. Cl. 428/220; 204/298.13; 204/192.29; 252/512; 252/515

(57) ABSTRACT

An object of the present invention is to provide a tin oxide target suitable for forming a transparent conductive film by a sputtering method, in particular, DC sputtering method, DC pulse sputtering method, AC sputtering method, and MF sputtering method. The present invention relates to a sputtering target for use in forming a transparent conductive film by a sputtering method, the sputtering target containing tin oxide as a main component and containing, as dopants, copper element and at least one element selected from the dopant group A consisting of niobium, tungsten, tantalum, bismuth, and molybdenum.

### TECHNICAL FIELD

The present invention relates to a sputtering target suitable for use in forming a transparent conductive film by a sputtering method, in particular, by the DC (direct-current) sputtering method, AC sputtering method, DC pulse sputtering method, and MF (medium-frequency) sputtering method.

The invention further relates to a transparent conductive film suitable for use as a transparent electrode in flat panel displays (FPDs) and to a process for producing the transparent conductive film.

The transparent conductive film of the invention can be advantageously formed from the sputtering target of the invention.

### BACKGROUND ART

In FPDs such as liquid-crystal displays (LCDs), plasma display panels (PDPs), and electroluminescent displays (ELDs) including organic EL displays, transparent conductive films have hitherto been used as the transparent electrodes formed on substrates. Known materials of the transparent conductive films include indium oxide materials, zinc oxide materials, and tin oxide materials. ITO (tin-doped indium oxide) is an especially famous indium oxide material and is in extensive use. The reasons why ITO is extensively used include the low resistance and satisfactory suitability for patterning thereof. However, it is known that indium is poor in reserve, and there is a desire for the development of a material usable as a substitute.

Tin oxide (SnO₂) is a material expected to be usable as a substitute for ITO. However, for imparting conductivity to tin oxide, it has been necessary to use antimony as a dopant, although there is a fear that antimony will pose an environmental problem in the future (see, for example, patent document 1).

Patent document 1: JP-A-10-330924

### DISCLOSURE OF THE INVENTION

### Problems that the Invention is to Solve

Dopants other than antimony, such as tungsten and tantalum, have hitherto been investigated (see, for example, Applied Physics Letters, Vol. 78, No. 3, p. 350 (2001)).

However, when tin oxide containing tungsten or tantalum only is used to produce a sputtering target, this sinter has a low density and hence low mechanical strength and does not withstand practical use as a sputtering target due to the frequent occurrence of erosion and cracking.

On the other hand, investigations have hitherto been made on tin oxide targets usable in sputtering methods such as the DC sputtering method, DC pulse sputtering method, AC sputtering method, and MF sputtering method, and such targets actually obtained are shown (see, for example, JP-A-2005-154820). However, films formed using the target disclosed in that document have a high electrical resistance. At present, no thin film having a specific resistance of 5×10⁻² Ωcm or lower, which is generally required of ITO substitute materials, has been obtained.

An object of the invention is to provide a tin oxide target capable of forming a low-resistance transparent conductive film by a sputtering method, in particular, the DC sputtering method, DC pulse sputtering method, AC sputtering method, and MF sputtering method.

Another object of the invention is to provide a transparent conductive film preferably formed from the tin oxide target and a process for producing the transparent conductive film.

### Means for Solving the Problems

The present inventors diligently made investigations in order to obtain a tin oxide target which has a sinter density suitable for sputtering methods (moderate relative density) and attains a moderate film-forming rate. As a result, they have found that by incorporating given amounts of at least one element selected from niobium, tungsten, tantalum, bismuth, and molybdenum and copper element as dopants into a tin oxide target, a target is obtained which has a sinter density and a surface sheet resistivity that make the target usable in sputtering methods, in particular, the DC sputtering method, DC pulse sputtering method, AC sputtering method, and MF sputtering method with excellent productivity.

The invention has been achieved based on that knowledge. The invention provides a sputtering target for use in forming a transparent conductive film by a sputtering method,

the sputtering target containing tin oxide as a main component and containing, as dopants, copper element and at least one element selected from the dopant group A consisting of niobium, tungsten, tantalum, bismuth, and molybdenum.

It is preferred that the sputtering target of the invention satisfies the following expressions (1) to (3) when the total amount of the elements of the dopant group A is expressed by M_{A} (at. %), the amount of the copper element is expressed by M_{Cu} (at. %), and the amount of the tin element contained in the sputtering target is expressed by M_{Sn} (at. %).

0.8<(M_{Sn})/(M_{Sn}+M_{A}+M_{Cu})<1.0 (1)

0.001<(M_{A})/(M_{Sn}+M_{A}+M_{Cu})<0.15 (2)

0.001<(M_{Cu})/(M_{Sn}+M_{A}+M_{Cu})<0.1 (3)

The M_{Sn} (at. %) means the proportion of the number of tin atoms to the number of all metal atoms in the target. The same applies to the M_{A} (at. %) and M_{Cu}, (at. %).

It is preferred that the sputtering target satisfies the following expressions (8) to (10) when the total amount of the elements of the dopant group A in the sputtering target is expressed by M_{A} (at. %), the amount of the copper element is expressed by M_{Cu} (at. %), and the amount of the tin element contained in the sputtering target is expressed by M_{Sn} (at. %).

0.85<(M_{Sn})/(M_{Sn}+M_{A}+M_{Cu})<0.99 (8)

0.005<(M_{A})/(M_{Sn}+M_{A}+M_{Cu})<0.10 (9)

0.001<(M_{Cu})/(M_{Sn}+M_{A}+M_{Cu})<0.08 (10)

The sputtering target of the invention preferably has a relative density of 80% or higher and a surface sheet resistivity of 9×10⁶ Ω/square or lower.

The invention further provides a transparent conductive film containing tin oxide as a main component,

the transparent conductive film containing, as dopants, copper element and at least one element selected from the dopant group A consisting of niobium, tungsten, tantalum, bismuth, and molybdenum.

It is preferred that the transparent conductive film of the invention satisfies the following expressions (4) to (6) when the total amount of the elements of the dopant group A is expressed by M_{A} (at. %), the amount of the copper element is expressed by M_{Cu} (at. %), and the amount of the tin element contained in the transparent conductive film is expressed by M_{Sn} (at. %).

0.8<(M_{Sn})/(M_{Sn}+M_{A}+M_{Cu})<1.0 (4)

0.001<(M_{A})/(M_{Sn}+M_{A}+M_{Cu})<0.15 (5)

0.001<(M_{Cu})/(M_{Sn}+M_{A}+M_{Cu})<0.1 (6)

It is preferred that the transparent conductive film satisfies the following expressions (11) to (13) when the total amount of the elements of the dopant group A is expressed by M_{A} (at. %), the amount of the copper element is expressed by M_{Cu} (at. %), and the amount of the tin element contained in the transparent conductive film is expressed by M_{Sn} (at. %).

0.85<(M_{Sn})/(M_{Sn}+M_{A}+M_{Cu})<0.99 (11)

0.005<(M_{A})/(M_{Sn}+M_{A}+M_{Cu})<0.10 (12)

0.001<(M_{Cu})/(M_{Sn}+M_{A}+M_{Cu})<0.08 (13)

The transparent conductive film of the invention preferably has a specific resistance of 5×10⁻² Ωcm or lower.

Furthermore, the transparent conductive film of the invention preferably has a carrier density of 8×10¹⁹/cm³ or higher. (In this specification, the density of electrons is expressed by a positive numerical value.)

The transparent conductive film of the invention preferably has a thickness of 1 μm or smaller.

Furthermore, the transparent conductive film of the invention preferably has a light absorptivity, as measured at a wavelength of 1,064 nm, of 3.8% or higher.

It is preferred that the transparent conductive film of the invention is formed by a sputtering method.

The invention furthermore provides a member for displays which has the transparent conductive film of the invention.

The invention still further provides a process for producing a transparent conductive film, the process comprising forming the transparent conductive film of the invention by a sputtering method using the sputtering target of the invention.

### ADVANTAGES OF THE INVENTION

The sputtering target of the invention has a high sinter density and a low surface sheet resistivity. Because of this, the target is suitable for use as a sputtering target in forming a transparent conductive film by sputtering methods, in particular, the DC sputtering method, DC pulse sputtering method, AC sputtering method, and MF sputtering method.

The transparent conductive film formed using the sputtering target of the invention compares favorably with conventional transparent conductive films in properties required of transparent electrodes for FPDs, such as specific resistance, carrier density, and visible light transmittance.

Furthermore, the sputtering target of the invention and the transparent conductive film formed therefrom do not contain indium, which is expensive. The transparent conductive film can hence be provided at low cost. In addition, since the transparent conductive film contains neither arsenic nor antimony, which both may arouse an environmental fear in future, this transparent conductive film is superior also from the standpoint of environment.

### BEST MODE FOR CARRYING OUT THE INVENTION

The sputtering target of the invention contains tin oxide as a main component and contains, as dopants, copper element and at least one element selected from the dopant group A consisting of niobium, tungsten, tantalum, bismuth, and molybdenum. The expression “contains tin oxide as a main component” means that the content of tin oxide in terms of tin element amount is higher than 80 at. % based on the total amount (M_{Sn}+M_{A}+M_{Cu}) (i.e., (M_{Sn})>80 at. %).

In the sputtering target of the invention, the element of the dopant group A (niobium, tungsten, tantalum, bismuth, and molybdenum) is contained as a dopant in the sinter target containing tin oxide as a main component (hereinafter referred to also as “tin oxide target”) for the purpose of imparting conductivity to the film to be formed by sputtering.

However, tin oxide targets containing at least one element in the dopant group A only have been unable to be used for forming a transparent electrode for FPDs by sputtering methods, in particular, by the DC sputtering method, DC pulse sputtering method, and MF sputtering method with excellent productivity, for any of the following reasons.

(1) Such tin oxide targets have a sinter density lower than 80% and hence cannot have sufficient mechanical strength. These targets do not withstand practical use as a sputtering target due to the frequent occurrence of erosion and cracking. The reason why the incorporation of at least one element in the dopant group A as the only dopant results in a low sinter density is as follows. The tin oxide vaporizes/condenses at high temperatures without causing particle rearrangement or grain boundary movement and hence densification does not occur during sintering.

(2) Even when such a sinter can be shaped into a sputtering target, the target obtained has a high sheet resistivity and hence a DC discharge, DC pulse discharge, and MF discharge cannot be conducted. The reason why the incorporation of at least one element in the dopant group A as the only dopant results in a high film surface sheet resistivity is that sufficient bonding among tin oxide particles is not attained in this case also and an electrical loss is caused around the bonding interface between the particles.

In the case of the sputtering target of the invention, the tin oxide target contains copper element as a dopant besides the at least one element in the dopant group A. Because of this, the tin oxide target of the invention has the property of being usable in sputtering methods, in particular, the DC sputtering method, DC pulse sputtering method, AC sputtering method, and MF sputtering method. Specifically, since this target has an increased sinter density, it has mechanical strength sufficient for shaping into a sputtering target. In addition, this target has sufficiently low surface resistance, specifically, a sufficiently low sheet resistivity.

In the field of ceramics, a low-melting substance is generally added as a sintering aid in order to heighten sinter density. Extensively used sintering aids for ceramics are, for example, oxides of Mg, Ca, Al, Ba, Y, Ti, Zr, Fe, Ce, Si, Zn, and the like.

The present inventors added various elements including those used as sintering aids for ceramics to a tin oxide target in order to obtain a target having a sinter density which makes the target usable in sputtering methods. As a result, they have found that copper oxide is more effective in heightening sinter density than the other additives and can attain densification even when added in a smaller amount. Furthermore, although copper element is generally considered to be ineffective in improving the carrier density of a film to be formed, the inventors have found that the addition of copper element is effective in heightening the carrier density of a film to be formed from a target having a composition within the specific compositional range shown in this description.

Moreover, the present inventors have found that compared to zinc and niobium, which are thought to be most effective sintering aids for targets, use of copper as a sintering aid has the following advantages: (1) copper can improve the relative density of the target even when added in a smaller amount than zinc or niobium (A sintering aid generally tends to impair rather than improve the performance of a film to be formed, and it is therefore thought that the smaller the amount of a sintering aid to be added, the better); and (2) because of having a higher carrier concentration, a smaller thickness and improved laser processability can be attained even when having the same sheet resistivity.

The sputtering target of the invention may contain one element selected from the dopant group A or may contain two or more elements selected therefrom. It is preferred that tantalum among the elements of the dopant group A is contained because this can impart a lower resistivity.

It is preferred that the sputtering target of the invention should satisfy the following expressions (1) to (3) when the total amount of the elements of the dopant group A is expressed by M_{A} (at. %), the amount of the copper element is expressed by M_{Cu} (at. %), and the amount of the tin element contained in the sputtering target is expressed by M_{Sn} (at. %).

0.8<(M_{Sn})/(M_{Sn}+M_{A}+M_{Cu})<1.0 (1)

0.001<(M_{A})/(M_{Sn}+M_{A}+M_{Cu})<0.15 (2)

0.001<(M_{Cu})/(M_{Sn}+M_{A}+M_{Cu})<0.1 (3)

In the sputtering target of the invention, the elements of the dopant group A mainly serve to improve the electrical conductivity of the target based on the carrier possessed thereby. Copper mainly functions as a sintering aid to enable the target to stably form a film at a high film-forming rate.

Although each element in the dopant group A and copper have the functions described above, it is not easy to use these two elements in combination. This is because even when two metals respectively having given properties are used in combination, the two metals do not always exhibit their properties inherent therein.

The total content of all elements other than the elements of the dopant group A, copper element, and tin element is preferably 10 at. % or lower, more preferably 5 at. % or lower, based on the total amount (M_{Sn}+M_{A}+M_{Cu}) from the standpoint of maintaining the relative density and sheet resistivity of the target.

Incidentally, when a film is formed from the target having such a composition, the film formed has almost the same composition as the target.

When the sputtering target of the invention satisfies the expressions (1) to (3) given above, it is easy to obtain a target having a relative density, which is determined with the following expression (7), of 80% or higher.

Relative density (%)=[(bulk density)/(true density)]×100 (7)

In the expression, the bulk density (g/cm³) is the density determined from the dry weight, submerged weight, and water-saturated weight of the target by the Archimedes method; and the true density is a theoretical density calculated from the theoretical densities inherent in the substances.

So long as the sputtering target has a relative density of 80% or higher, this target has sufficient mechanical strength which enables the target to withstand practical use as a target for sputtering.

The sputtering target of the invention preferably satisfies the expressions (1) to (3) given above because the target satisfying these expressions is apt to have a surface sheet resistivity of 9×10⁶ Ω/square or lower.

So long as the target has a surface sheet resistivity of 9×10⁶ Ω/square or lower, this target has sufficiently low surface resistance and hence is suitable for use as a target for sputtering, in particular, for DC sputtering, DC pulse sputtering, and MF sputtering.

The relative density of the sputtering target is preferably 80% or higher, more preferably 90% or higher.

The sheet resistivity of the surface of the sputtering target is preferably 9×10⁶ Ω/square or lower, more preferably 1×10⁶ Ω/square or lower.

It is more preferred for the sputtering target of the invention that the M_{A}, M_{Cu}, and M_{Sn}, satisfy the following expressions.

0.85<(M_{Sn})/(M_{Sn}+M_{A}+M_{Cu})<0.99 (8)

0.005<(M_{A})/(M_{Sn}+M_{A}+M_{Cu})<0.10 (9)

0.001<(M_{Cu})/(M_{Sn}+M_{A}+M_{Cu})<0.08 (10)

It is more preferred that (M_{A})/(M_{Sn}+M_{A}+M_{Cu})<0.05.

It is also more preferred that 0.003<(M_{Cu})/(M_{Sn}+M_{A}+M_{Cu}). Furthermore, it is more preferred that (M_{Cu})/(M_{Sn}+M_{A}+M_{Cu})<0.03.

Although the addition of copper element is effective to improve the sinter density of the tin oxide target, too large addition amounts of copper element result in a reduced film-forming rate when this tin oxide target is used to conduct sputtering. So long as the copper element content in the sputtering target of the invention satisfies expression (10), this target has strength sufficient for sputtering methods and use of this target in sputtering does not result in a reduced film-forming rate.

The sputtering target of the invention can be produced by an ordinary procedure for producing a sintered oxide target. Namely, the target may be obtained by mixing raw materials so as to result in a desired composition, pressing the powder mixture, followed by sintering in the air atmosphere at a high temperature (e.g., 1,300° C. or 1,500° C.) and atmospheric pressure.

At high temperatures, it is necessary to conduct the sintering in the air atmosphere. At a reduced pressure or in an argon atmosphere, the tin oxide is apt to decompose and vaporize and the target is less apt to be densified. It is therefore preferred to conduct the sintering in an oxygen-containing atmosphere such as air. For example, the sintering is carried out in air under the temperature conditions of 1,000-1,600° C., preferably 1,300-1,600° C.

In the case of sintering in air, a target can be produced, for example, in the following manner. A tin oxide powder and a powder of an oxide of each dopant are prepared. These powders are mixed together in a given proportion. In this mixing, water is used as a dispersion medium and the ingredients are mixed by the wet ball mill method. Subsequently, the resultant powder is dried, thereafter packed in a rubber mold, and pressed with a cold isostatic pressing apparatus (CIP apparatus) at a pressure of 1,500 kg/cm². Thereafter, sintering is carried out by holding the powder compact in the air at a temperature of 1,000-1,600° C., preferably 1,300-1,600° C., for 2 hours to obtain a sinter. This sinter is machined into a given size to produce a target material. This target material is metal-bonded to a backing plate made of a metal, e.g., copper, to produce a target.

The tin oxide powder has a particle size of preferably 10 μm or smaller, more preferably 5 μm or smaller, in terms of average particle size. The particle size thereof is even more preferably 1 μm or smaller. On the other hand, the powder of an oxide of each dopant has a particle diameter of preferably 10 μm or smaller, more preferably 5 μm or smaller, in terms of average particle diameter. The particle diameter thereof is even more preferably 1 μm or smaller. When the sinter obtained by the procedure described above is examined with an SEM for crystal grain diameter, this sinter is ascertained to have a crystalline grain size of from 1 to 50 μm. From the relative density of the sinter obtained by the procedure described above, it can be ascertained that the sinter has a dense structure having a small amount of voids among the grains.

The transparent conductive film of the invention contains tin oxide as a main component and contains, as dopants, copper element and at least one element selected from the dopant group A consisting of niobium, tungsten, tantalum, bismuth, and molybdenum. The transparent conductive film contains substantially no antimony and substantially no indium. The expression “contains tin oxide as a main component” means that the content of tin oxide in terms of tin element amount is higher than 80 at. % based on the total amount (M_{Sn}+M_{A}+M_{Cu}) (i.e., (M_{Sn})>80 at. %).

The transparent conductive film of the invention is preferably formed by sputtering, in particular, DC sputtering, DC pulse sputtering, AC sputtering, or MF sputtering, using the sputtering target of the invention.

In general, sputtering methods, by which an even thin film is easily obtained and which are less apt to cause environmental pollution, are suitable for use in forming a film having a large area. The sputtering methods are roughly divided into: the radio-frequency (RF) sputtering method in which a radio-frequency power source is used; direct-current (DC) sputtering method in which a direct-current power source is used; direct-current (DC) pulse sputtering method; AC sputtering method in which direct-current power sources are used while being switched; and medium-frequency (MF) sputtering method in which a medium-frequency power source is used. The RF sputtering method is superior in that an electrically insulating material can be used as a target. However, the radio-frequency power source has a high cost and a complicated structure, and the RF sputtering method is undesirable for use in forming a film having a large area.

In contract, the DC sputtering method, DC pulse sputtering method, AC sputtering method, and MF sputtering method have an advantage that apparatus operation is easy because a direct-current power source or medium-frequency power source having a simple device structure is used, although target materials are limited to materials having satisfactory conductivity. In addition, those methods are film-forming techniques which are advantageous from the standpoint of film thickness control. Consequently, the DC sputtering method, DC pulse sputtering method, AC sputtering method, and MF sputtering method, which have excellent productivity, are preferred techniques for industrial film-forming methods. Incidentally, to use not the RF sputtering method but the DC sputtering method, DC pulse sputtering method, AC sputtering method, or MF sputtering method as a sputtering method is one of important factors which govern whether commercialization is possible from the standpoint of productivity.

It should, however, be noted that the transparent conductive film of the invention is not particularly limited in the method used for producing the same, so long as the transparent conductive film satisfies the feature described above. Consequently, the transparent conductive film may be one formed by another sputtering method such as the RF sputtering method, or may be one formed by another film-forming technique such as the CVD method, sol-gel method, or PLD method.

In the case where the film is formed by a sputtering method, it is preferred to conduct sputtering in an oxidizing atmosphere. The term oxidizing atmosphere means an atmosphere containing an oxidizing gas. The term oxidizing gas means an oxygen-atom-containing gas such as O₂, H₂O, CO, or CO₂. The concentration of the oxidizing gas considerably influences film properties such as, e.g., the electrical conductivity and light transmittance of the film. It is therefore necessary to optimize the concentration of the oxidizing gas by regulating the conditions to be used, such as the apparatus, substrate temperature, and sputtering pressure.

A preferred gas for sputtering is an Ar—O₂ gas (Ar/O₂ mixture gas) system or an Ar—CO₂ gas (Ar/CO₂ mixture gas) system because gas composition is easy to regulate when a transparent film having low resistance is to be produced. In particular, an Ar—CO₂ gas system is more preferred because this gas system is superior in the regulation.

In the Ar—O₂ gas system, the O₂ concentration thereof is preferably 1-25% by volume because a transparent film having low resistance is obtained with this gas system. In case where the O₂ concentration is lower than 1% by volume, there is a possibility that the film might have yellowed and have increased resistance. The O₂ concentration is more preferably 0.5-25% by volume. In case where the O₂ concentration is lower than 0.5% by volume or exceeds 25% by volume, there is a possibility that the film might have increased resistance.

On the other hand, in the Ar—CO₂ gas system, the CO₂ concentration thereof is preferably 10-50% by volume because a transparent film having low resistance is obtained with this gas system. In case where the CO₂ concentration is lower than 10% by volume, there is a possibility that the film might have yellowed and have increased resistance. In case where the CO₂ concentration exceeds 50% by volume, there is a possibility that the film might have increased resistance. However, there are cases where a colored film or high resistance is desired in some applications. In such cases, the O₂ concentration and the CO₂ concentration should not be construed as being limited to those shown above.

The transparent conductive film of the invention can be produced, for example, in the following manner. A magnetron DC sputtering apparatus is used, and the target described above is used. A chamber is evacuated to 10⁻⁷-10⁻⁴ Torr (10⁻⁵-10⁻² Pa). In case where the internal pressure of the chamber exceeds 10⁻⁴ Torr (exceeds 10⁻² Pa), the residual water remaining in the vacuum exerts an influence and hence resistance regulation is difficult. In case where the internal pressure of the chamber is lower than 10⁻⁷ Torr (lower than 10⁻⁵ Pa), evacuation requires much time, resulting in poor productivity. The power density during sputtering (value obtained by dividing applied electric power by the area of the surface of the target) is preferably 1-10 W/cm². In case where the power density is lower than 1 W/cm², discharge is unstable. In case where the power density exceeds 10 W/cm², there is a higher possibility that the target might break due to the heat generated. The sputtering pressure is preferably 10⁻⁴-10⁻¹ Torr (10⁻²-10 Pa). In case where the sputtering pressure is lower than 10⁻⁴ Torr (lower than 10⁻² Pa) or exceeds 10⁻¹ Torr (exceeds 10 Pa), discharge tends to be unstable.

It is preferred that the transparent conductive film of the invention satisfies the following expressions (4) to (6) when the total amount of the elements of the dopant group A is expressed by M_{A} (at. %), the amount of the copper element is expressed by M_{Cu}, (at. %), and the amount of the tin element contained in the transparent conductive film is expressed by M_{Sn} (at. %).

0.8<(M_{Sn})/(M_{Sn}+M_{A}+M_{Cu})<1.0 (4)

0.001<(M_{A})/(M_{Sn}+M_{A}+M_{Cu})<0.15 (5)

0.001<(M_{Cu})/(M_{Sn}+M_{A}+M_{Cu})<0.1 (6)

The elements of the dopant group A mainly serve to improve the electrical conductivity of the target based on the carrier possessed thereby. Because of this, the film formed has high conductivity. Copper mainly functions as a sintering aid, whereby stable film formation is possible at a high film-forming rate.

The total content of all elements other than the elements of the dopant group A, copper element, and tin element is preferably 10 at. % or lower, more preferably 5 at. % or lower, based on the total amount (M_{Sn}+M_{A}+M_{Cu}) from the standpoint of maintaining low resistivity and film-forming conditions.

When the expressions (4) to (6) given above are satisfied, a transparent conductive film having a specific resistance of 5×10⁻² Ωcm or lower is easy to obtain. This film is suitable for use as a transparent electrode for FPDs. The specific resistance of the transparent conductive film is desirable 5×10⁻² Ωcm or lower, preferably 1×10⁻² Ωcm or lower, more preferably 0.5×10⁻² Ωcm or lower, even more preferably 9×10⁻³ Ωcm or lower. Furthermore, a transparent conductive film having a carrier density of 8×10¹⁹/cm³ or higher is easy to obtain, and this film is suitable for use as a transparent electrode for FPDs.

The transparent conductive film of the invention preferably has a thickness of 1 μm or smaller. So long as the thickness of the transparent conductive film is 1 μm or smaller, there is no possibility that this transparent conductive film might have optical defects such as haze. The thickness of the transparent conductive film is more preferably 0.4 μm or smaller, even more preferably 0.25 μm or smaller. The thickness of the transparent conductive film is preferably 50 nm or larger.

It is preferred that the transparent conductive film of the invention has excellent transparency. Specifically, the visible light transmittance thereof is preferably 80% or higher.

The transparent conductive film of the invention preferably has a light absorptivity, as measured at a wavelength of 1,064 nm, of 3.8% or higher. When the transparent conductive film has a light absorptivity, as measured at a wavelength of 1,064 nm, of 3.8% or higher, this film has excellent processability especially with a YAG laser and is hence suitable for use as a transparent electrode for FPDs of PDPs.

The transparent conductive film of the invention contains substantially no indium, which is expensive. The transparent conductive film can hence be provided at low cost. Furthermore, the transparent conductive film of the invention contains substantially no antimony, which may arouse an environmental fear in future. The transparent conductive film is hence superior also from the standpoint of environment and has a reduced specific resistance. Another advantage of containing no antimony includes providing excellent resistance against glass frit erosion.

The content of indium element in the transparent conductive film is preferably 0.1% (at. %) or lower. The content of antimony element in the transparent conductive film is preferably 0.1% (at. %) or lower.

From the standpoint of further reducing the specific resistance of the transparent conductive film, it is preferred that the transparent conductive film of the invention satisfies the following expressions (11) to (13).

0.85<(M_{Sn})/(M_{Sn}+M_{A}+M_{Cu})<0.99 (11)

0.005<(M_{A})/(M_{Sn}+M_{A}+M_{Cu})<0.10 (12)

0.001<(M_{Cu})/(M_{Sn}+M_{A}+M_{Cu})<0.08 (13)

In expressions (11) to (13), M_{A}, M_{Cu}, and M_{Sn} have the same meanings as in expressions (4) to (6).

It is more preferred that (M_{A})/(M_{Sn}+M_{A}+M_{Cu})<0.05.

It is also more preferred that 0.003<(M_{Cu})/(M_{Sn}+M_{A}+M_{Cu}). Furthermore, it is more preferred that (M_{Cu})/(M_{Sn}+M_{A}+M_{Cu})<0.03.

The member for displays of the invention may be used as a substrate for FPDs such as PDPs, in particular, as the front-side substrate of an FPD. For example, the member for displays is constituted of a glass substrate or resin substrate and, formed thereon as a transparent electrode, the transparent conductive film of the invention described above.

The glass substrate is not particularly limited. Examples thereof include conventionally known various glass substrates (soda-lime glasses, alkali-free glasses, and high-strain-point glasses for PDPs). The size and thickness thereof are also not particularly limited. For example, it is preferred to use a glass substrate having length and width dimensions of about 400-3,000 mm each. The thickness thereof is preferably 0.7-3.0 mm, more preferably 1.5-3.0 mm.

Besides being used in PDPs, the member for displays of the invention can be used as a substrate for various FPDs. Examples of such FPDs include liquid-crystal displays (LCDs), electroluminescent displays (ELDs) including organic EL displays, and field emission displays (FEDs).

### EXAMPLES

The invention will be explained below based on Examples and Comparative Examples. The Examples are mere examples and the invention should not be construed as being limited by these Examples in any way. Namely, the comprehensive scope of the invention is determined by the scope of the claims, and includes various modifications besides the following Examples.

### Examples 1 to 12

Powders of SnO₂, Ta₂O₅, WO₃, Nb₂O₅, Bi₂O₃, and CuO which each had a purity corresponding to 99.9% and a particle diameter of 5 μm or smaller were used. These powders were mixed together so as to result in the metallic-element proportions shown in Table 1. In each of Examples 6 to 8, two elements of the dopant group A were used. Specifically, in Example 6, bismuth was used in an amount of 1.5 (at. %) based on the total amount (M_{Sn}+M_{A}+M_{Cu}) (hereinafter, each proportion is based on the total amount (M_{Sn}+M_{A}+M_{Cu})) and niobium was used in an amount of 6.0 (at. %). In Example 7, tantalum and niobium were used in amounts of 1.0 (at. %) and 3.5 (at. %), respectively. In Example 8, tungsten and niobium were used in amounts of 1.0 (at. %) and 3.5 (at. %), respectively. In Example 12, tantalum and niobium were used in amounts of 4.5 (at. %) and 0.5 (at. %), respectively.

The powders mixed together were further mixed by means of a ball mill, and the resultant powder mixture was press-molded. Thereafter, sintering was carried out for 4 hours at 1,450° C. in the air atmosphere in Examples 1 to 5 or at 1,500° C. in the air atmosphere in Examples 6 to 12. The resultant sintered oxide was finished into a target shape by machining. The composition, relative density, and surface resistance (surface sheet resistivity) of each sintered oxide target obtained are as shown in Table 1. The surface sheet resistivity of each target was measured with a surface resistance meter (Loresta, manufactured by Mitsubishi Petrochemical). The relative density of each target was determined using the following expression (7).

Relative density (%)=[(bulk density)/(true density)]×100 (7)

In the expression, the bulk density (g/cm³) is the density determined from the dry weight, submerged weight, and water-saturated weight of the target by the Archimedes method; and the true density is a theoretical density calculated from the theoretical densities inherent in the substances.

A high-strain-point glass having a thickness of 2.8 mm (PD200, manufactured by Asahi Glass Co., Ltd.; visible light transmittance of the substrate, 91%) was prepared as a glass substrate. This glass substrate was cleaned and then set on a substrate holder. The sintered oxide target having the composition shown in Table 1 was attached to the cathode of a magnetron DC sputtering apparatus. The film-forming chamber of this sputtering apparatus was evacuated to a vacuum. Thereafter, a film containing tin oxide as a main component and having a thickness of about 150 nm was formed on the glass substrate by the DC sputtering method. As a sputtering gas was used an argon/oxygen mixture gas. The substrate temperature was 250° C. The pressure during the film formation was 0.5 Pa.

By changing the flow rate ratio between the argon gas and the oxygen gas, a thin film which was transparent and had low electrical resistance was able to be formed. Table 2 shows the composition, visible light transmittance, and specific resistance of each film obtained while regulating the gas ratio so as to result in a minimal electrical resistance. The composition, visible light transmittance, and specific resistance of each film were determined by the following methods.

(1) Composition: A 300-nm film was produced under the same process conditions as those used for the film formation on the glass substrate. A fluorescent X-ray apparatus (RIX3000, manufactured by Rigaku Industrial Corp.) was used to determine the quantity of fluorescence emitted from each metallic element, and the amount of each metallic element and the proportions of the metallic elements were calculated based on the fundamental parameter theory.

(2) Visible Light Transmittance: In accordance with JIS-R3106 (1998), the obtained film-coated glass substrate was examined with a spectrophotometer (U-4100, manufactured by Shimadzu Corp.) to obtain a transmission spectrum for the coated substrate, and the visible light transmittance of the film-coated glass substrate was calculated from the spectrum.

(3) Specific Resistance: Resistivity was measured with a surface resistance meter (Loresta, manufactured by Mitsubishi Petrochemical).

As apparent from Table 1, the sintered oxide targets shown in Examples 1 to 12 each had a relative density of 80% or higher and a surface resistivity of 9×10⁶ Ω/square or lower. These sintered oxide targets were ascertained to be sputtering targets usable in the DC sputtering, DC pulse sputtering, and MF sputtering methods. As apparent from Table 2, the films obtained in Examples 1 to 12 each have a visible light transmittance of 85% or higher and a specific resistance of 1×10⁻² Ωcm or lower and can be suitable for use as a transparent electrode for FPDs of PDPs. Furthermore, since these films have a light absorptivity of 3.8% or higher at a wavelength of 1,064 nm, the films have excellent laser processability and are hence suitable for use as a transparent electrode for FPDs of PDPs.

### Comparative Examples 1 to 4

Production of sintered oxide targets having the compositions shown in Table 1 was attempted in the same manner as in the Examples.

However, with respect to the target constituted of tin oxide only (Comparative Example 1) and the targets to which a dopant A element had been added as the only dopant (Comparative Examples 2 and 3), each sinter had a density as low as 60% or below. These sinters cracked when machined into a target shape, and target production therefrom was impossible.

When the target obtained in Comparative Example 4, to which tantalum and niobium had been added in amounts of 4.5 (at. %) and 0.5 (at. %), respectively, and the target obtained in Example 12, which had the same elemental composition as that comparative target except that copper had been further added in an amount of 0.2 (at. %), were compared with each other in properties of the film obtained therefrom by sputtering, it was found that Example 12 was superior in all the properties shown in Table 1 and Table 2.

TABLE 1
Target composition, relative density, and sheet resistivity

| | Elements | (Sn)/ | (M_{A})/ | (Cu)/ | Relative density | Sheet resistivity | |
|---|---|---|---|---|---|---|---|
| Example | added | (Sn + M_{A} + Cu) | (Sn + M_{A} + Cu) | (Sn + M_{A} + Cu) | (%) | (Ω/square) | |
| Example 1 | M_{A} = Ta | 0.961 | 0.029 | 0.010 | 97.5 | 150 | k |
| | Cu was added | | | | | | |
| Example 2 | M_{A} = Ta | 0.920 | 0.060 | 0.020 | 99.1 | 2 | k |
| | Cu was added | | | | | | |
| Example 3 | M_{A} = Ta | 0.850 | 0.100 | 0.050 | 98.2 | 80 | |
| | Cu was added | | | | | | |
| Example 4 | M_{A} = W | 0.961 | 0.029 | 0.010 | 92.7 | 200 | k |
| | Cu was added | | | | | | |
| Example 5 | M_{A} = W | 0.847 | 0.103 | 0.050 | 93.4 | 120 | |
| | Cu was added | | | | | | |
| Example 6 | M_{A} = Bi + Nb | 0.915 | 0.075 | 0.010 | 98.7 | 40 | k |
| | Cu was added | | | | | | |
| Example 7 | M_{A} = Ta + Nb | 0.945 | 0.045 | 0.010 | 98.2 | 0.06 | M |
| | Cu was added | | | | | | |
| Example 8 | M_{A} = W + Nb | 0.945 | 0.045 | 0.010 | 94.1 | 50 | k |
| | Cu was added | | | | | | |
| Example 9 | M_{A} = Ta | 0.946 | 0.050 | 0.004 | 98.5 | 70 | |
| | Cu was added | | | | | | |
| Example 10 | M_{A} = Ta | 0.958 | 0.040 | 0.002 | 97.0 | 130 | |
| | Cu was added | | | | | | |
| Example 11 | M_{A} = Ta + Bi | 0.958 | 0.040 | 0.002 | 98.3 | 200 | |
| | Cu was added | | | | | | |
| Example 12 | M_{A} = Ta + Nb | 0.948 | 0.050 | 0.002 | 98.1 | 70 | |
| | Cu was added | | | | | | |
| Comparative | M_{A} was not added | 1.000 | 0.000 | 0.000 | 51.8 | 40 | k |
| Example 1 | Cu was not added | | | | | | |
| Comparative | M_{A} = W | 0.970 | 0.030 | 0.000 | 43.0 | 20 | M |
| Example 2 | Cu was not added | | | | | | |
| Comparative | M_{A} = Ta | 0.970 | 0.030 | 0.000 | 49.4 | 35 | M |
| Example 3 | Cu was not added | | | | | | |
| Comparative | M_{A} = Ta + Nb | 0.950 | 0.050 | 0.000 | 91.7 | 500 | |
| Example 4 | Cu was not added | | | | | | |

TABLE 2
Film composition, visible light transmittance, specific resistance, carrier density, and light absorptivity at 1,064 nm

| | | | | | Visible light | Specific | Carrier | Light absorptivity at |
|---|---|---|---|---|---|---|---|---|
| | | (Sn)/ | (M_{A})/ | (Cu)/ | transmittance | Resistance | density | 1,064 nm |
| Example | Elements added | (Sn + M_{A} + Cu) | (Sn + M_{A} + Cu) | (Sn + M_{A} + Cu) | (%) | (Ωcm) | (/cm³) | (%) |
| Example 1 | M_{A} = Ta | 0.961 | 0.029 | 0.010 | 85.3 | 5.8E−03 | 1.3E+20 | 4.2 |
| | Cu was added | | | | | | | |
| Example 2 | M_{A} = Ta | 0.920 | 0.060 | 0.020 | 86.1 | 4.4E−03 | 1.6E+20 | 4.5 |
| | Cu was added | | | | | | | |
| Example 3 | M_{A} = Ta | 0.850 | 0.100 | 0.050 | 85.8 | 5.1E−03 | 1.1E+20 | 4.1 |
| | Cu was added | | | | | | | |
| Example 4 | M_{A} = W | 0.961 | 0.029 | 0.010 | 85.5 | 6.7E−03 | 2.0E+20 | 4.1 |
| | Cu was added | | | | | | | |
| Example 5 | M_{A} = W | 0.847 | 0.103 | 0.050 | 85.9 | 7.6E−03 | 1.5E+20 | 4.0 |
| | Cu was added | | | | | | | |
| Example 6 | M_{A} = Bi + Nb | 0.915 | 0.075 | 0.010 | 86.8 | 4.7E−03 | 6.0E+19 | 3.8 |
| | Cu was added | | | | | | | |
| Example 7 | M_{A} = Ta + Nb | 0.945 | 0.045 | 0.010 | 86.3 | 5.0E−03 | 1.8E+20 | 4.0 |
| | Cu was added | | | | | | | |
| Example 8 | M_{A} = W + Nb | 0.945 | 0.045 | 0.010 | 86.0 | 6.1E−03 | 1.6E+20 | 3.9 |
| | Cu was added | | | | | | | |
| Example 9 | M_{A} = Ta | 0.946 | 0.050 | 0.004 | 85.4 | 5.3E−03 | 2.5E+20 | 4.3 |
| | Cu was added | | | | | | | |
| Example 10 | M_{A} = Ta | 0.958 | 0.040 | 0.002 | 85.8 | 5.7E−03 | 1.2E+20 | 4.0 |
| | Cu was added | | | | | | | |
| Example 11 | M_{A} = Ta + Bi | 0.958 | 0.040 | 0.002 | 85.1 | 6.0E−03 | 1.6E+20 | 4.2 |
| | Cu was added | | | | | | | |
| Example 12 | M_{A} = Ta + Nb | 0.948 | 0.050 | 0.002 | 85.2 | 5.1E−03 | 2.0E+20 | 4.4 |
| | Cu was added | | | | | | | |
| Comparative | M_{A} = Ta + Nb | 0.950 | 0.050 | 0.000 | 83.8 | 9.2E−03 | 8.0E+19 | 2.9 |
| Example 4 | Cu was not added | | | | | | | |

While the invention has been described in detail and with reference to specific embodiments thereof, it will be apparent to one skilled in the art that various changes and modifications can be made therein without departing from the spirit and scope thereof.

This application is based on Japanese Patent Application No. 2007-064690 filed on Mar. 14, 2007, the contents thereof being herein incorporated by reference.

### INDUSTRIAL APPLICABILITY

The sputtering target of the invention is suitable for use in forming a transparent conductive film by sputtering methods, in particular, by the DC sputtering method, DC pulse sputtering method, AC sputtering method, and MF sputtering method.

The transparent conductive film obtained by the invention is excellent in transparency and conductivity and has excellent properties when used as a transparent electrode of an FPD. Since this transparent conductive film does not contain indium, which is expensive, the transparent conductive film can be provided at low cost. Since this transparent conductive film contains neither arsenic nor antimony, which both may arouse an environmental fear in future, the transparent conductive film is superior also from the standpoint of environment. In addition, application of the laser patterning technology, which has made remarkable progress in recent years, to this film is useful because a high-precision electrode pattern can be easily formed on a glass or plastic substrate, film substrate, or crystal substrate.

1. A sputtering target for forming a transparent conductive film by a sputtering method,
the sputtering target containing tin oxide as a main component and containing, as dopants, copper element and at least one element selected from the dopant group A consisting of niobium, tungsten, tantalum, bismuth, and molybdenum.

2. The sputtering target according to claim 1, wherein the following expressions (1) to (3) are satisfied when the total amount of the elements of the dopant group A in the sputtering target is expressed by M_{A} (at. %), the amount of the copper element is expressed by M_{Cu}, (at. %), and the amount of the tin element contained in the sputtering target is expressed by M_{Sn} (at. %).
0.8<(M_{Sn})/(M_{Sn}+M_{A}+M_{Cu})<1.0 (1)
0.001<(M_{A})/(M_{Sn}+M_{A}+M_{Cu})<0.15 (2)
0.001<(M_{Cu})/(M_{Sn}+M_{A}+M_{Cu})<0.1 (3)

3. The sputtering target according to claim 1, wherein the following expressions (8) to (10) are satisfied when the total amount of the elements of the dopant group A in the sputtering target is expressed by M_{A} (at. %), the amount of the copper element is expressed by M_{Cu} (at. %), and the amount of the tin element contained in the sputtering target is expressed by M_{Sn} (at. %).
0.85<(M_{Sn})/(M_{Sn}+M_{A}+M_{Cu})<0.99 (8)
0.005<(M_{A})/(M_{Sn}+M_{A}+M_{Cu})<0.10 (9)
0.001<(M_{Cu})/(M_{Sn}+M_{A}+M_{Cu})<0.08 (10)

4. The sputtering target according to claim 1, which has a relative density of 80% or higher and a surface sheet resistivity of 9×10⁶ Ω/square or lower.

5. A transparent conductive film containing tin oxide as a main component,
the transparent conductive film containing, as dopants, copper element and at least one element selected from the dopant group A consisting of niobium, tungsten, tantalum, bismuth, and molybdenum.

6. The transparent conductive film according to claim 5, wherein the following expressions (4) to (6) are satisfied when the total amount of the elements of the dopant group A is expressed by M_{A} (at. %), the amount of the copper element is expressed by M_{Cu}, (at. %), and the amount of the tin element contained in the transparent conductive film is expressed by M_{Sn} (at. %).
0.8<(M_{Sn})/(M_{Sn}+M_{A}+M_{Cu})<1.0 (4)
0.001<(M_{A})/(M_{Sn}+M_{A}+M_{Cu})<0.15 (5)
0.001<(M_{Cu})/(M_{Sn}+M_{A}+M_{Cu})<0.1 (6)

7. The transparent conductive film according to claim 5, wherein the following expressions (11) to (13) are satisfied when the total amount of the elements of the dopant group A is expressed by M_{A} (at. %), the amount of the copper element is expressed by M_{Cu}, (at. %), and the amount of the tin element contained in the transparent conductive film is expressed by M_{Sn} (at. %).
0.85<(M_{Sn})/(M_{Sn}+M_{A}+M_{Cu})<0.99 (11)
0.005<(M_{A})/(M_{Sn}+M_{A}+M_{Cu})<0.10 (12)
0.001<(M_{Cu})/(M_{Sn}+M_{A}+M_{Cu})<0.08 (13)

8. The transparent conductive film according to claim 5, which has a specific resistance of 5×10⁻² Ωcm or lower.

9. The transparent conductive film according to claim 5, which has a carrier density of 8×10¹⁹/cm³ or higher.

10. The transparent conductive film according to claim 5, which has a thickness of 1 μm or smaller.

11. The transparent conductive film according to claim 5, which has a light absorptivity, as measured at a wavelength of 1,064 nm, of 3.8% or higher.

12. The transparent conductive film according to claim 5, which has been formed by a sputtering method.

13. A member for displays which has the transparent conductive film according to claim 5.

14. A process for producing a transparent conductive film, the process comprising forming a transparent conductive film by a sputtering method using the sputtering target according to claim 1.
